(19) United States
(12) Patent Application Publication
(10) Pub. No.: US 2021/0028774 A1
(43) Pub. Date: Jan. 28, 2021

(54) Analog function generator with digital instrumentation methods for output signal

(71) Applicant: Ali W. Daher, Hadat (LB)

(72) Inventor: Ali W. Daher, Hadat (LB)

(21) Appl. No.: 16/524,103

(22) Filed: Jul. 28, 2019

(51) Int. Cl. H03K 4/06; H03L 7/085; G06F 1/03

(52) U.S. Cl. CPC H03K 4/06; G06F 1/0328; H03L 7/085

(57) ABSTRACT

The present invention relates to a function generator made of one apparatus which stabilizes the amplitude of an oscillating triangle signal while canceling offset in the preferred embodiment. A second apparatus is provided which manipulates the stable triangle wave to generate signals of different shapes. The signal shape can be chosen using toggle switches, before setting the amplitude and offset level by an operator. The frequency can be manipulated by editing the original triangle oscillator circuit. A third apparatus measures the amplitudes, offset and pulse width using original software techniques based on specific conditioning circuits, which are coupled to a microcontroller. The microcontroller also measures the frequency of a square wave using hysteresis with two overlapping frequency measurement libraries.

An apparatus for gain and offset control in this patent application is based on a previous research publication which is cited in the reference section.

### BACKGROUND

The present invention relates to an analog function generator with adjustable frequency, amplitude, offset, and a variety of signal shapes or functions. More particularly, the manipulated signal is monitored and displayed by a microprocessor with specialized circuits and software.

Function generators are used by instructors in a class setting along with an oscilloscope to teach beginning students in engineering. These devices are also used by practicing design engineers in the testing phases, of developing an electronic device. Usually, the operator defines the shape, amplitude, frequency, and offset of the signal which suite the particular application or demonstration.

Modern function generators utilize Direct Digital Synthesis (DDS) to generate oscillating signals, which is very well known in the art. DDS generates oscillating signals by digital means, which are discontinuous. These discontinuous signals are passed through a Low Pass Filter (LPF) to remove the discontinuities and produce an analog output. Furthermore, the output frequency should be significantly lower than the operating frequency of the microprocessor being used, and in some cases, a DDS dedicated Integrated Circuit may be used. It should be noted that in DDS, the output signal may not be fed-back and monitored to maintain stable offset and peak-to-peak amplitude while keeping a wide dynamic range, concerning voltages and frequency.

In the present invention, a triangle wave is generated using an oscillator, which passes through a stabilizer. The stable triangle wave is used to derive signals of other shapes, but with the same frequency, amplitude, and offset. The output signal characteristics are read by a digital instrumentation system, which implements different methods for measuring each attribute of the signal.

Signals that are generated using oscillators tend to vary in amplitude and offset over a wide range of frequencies. So, the model is shown in FIG. 1, which was proposed in a previous publication of mine, is used to implement the stabilizer used in the present invention.

### BRIEF SUMMARY OF THE INVENTION

A function generator is provided which has a triangle wave as input from an oscillator with adjustable oscillation frequency. This function generator is comprised of a first apparatus for stabilizing the triangle wave by means of positive and negative peak detection, by computing peak-to-peak amplitude and offset, and comparing these computed values to reference voltages, where the output of the comparators being amplified an integrated, and then fed-back to the input until offset and amplitude are stable and equal to fixed reference values.

The function generator contains a second apparatus which converts the stable triangle wave output of the first apparatus into signals of different functions but with the same amplitude, and offset, which is zero. The signals are being amplified or attenuated after conversion to make sure signal characteristics are identical. The signal shapes are being switched by an operator from one to the other using toggle switches.

A second apparatus is provided to manipulate the chosen function by coupling the signal to a potentiometer, an amplifier, and a summing circuit to change the offset and peak-to-peak amplitude.

A third apparatus measures the frequency, offset, Pulse Width Modulation (PWM) Pulse width, and the maximum and minimum peaks of the signal, which are manipulated by an operator regardless of whether the signal is DC or AC. The apparatus reads the conditioned PWM control, and offset, along with the outputs of the peak detectors using a microcontroller. Also, the apparatus reads the frequency of the square wave output on two pins. The software code of the microcontroller calculates the actual values of the signal characteristics and displays these values on a Liquid Crystal Display (LCD).

The stabilizer is an automatic gain control apparatus for stabilizing the peak-to-peak amplitude and offset of any oscillating signal simultaneously, which is comprised of a variable gain amplifier for maintaining the amplitude of the oscillating signal, a summing circuit to change the offset level, two peak detectors, where the first determines the positive peak of the signal and other determines the negative peak. The stabilizer also comprises of a means of computing the peak-to-peak amplitude of and the offset of the signal, a method of comparing the calculated amplitude and offset to a fixed reference voltages, and an amplifier for amplifying the difference between the amplitude and the Amp reference voltage, an amplifier for amplifying the difference between the offset voltages, and a means of integrating the amplified differences using a non-inverting integrator for the amplitude, and an inverting integrator for the offset. The outputs of the integrators are fed-back to the Variable gain amplifier and the summing circuit to complete the loop.

The variable gain amplifier comprises a conditioning circuit for bringing the AC signal to positive DC, a Mosfet acting a voltage controlled resistor, where the drain of the Mosfet being coupled to an amplifier to increase the gain to well above unity.

An apparatus is used for generating signals of different shapes and magnitudes, which relies on a variable frequency stable triangle wave, as a reference. The apparatus is comprised of a means of converting the triangle wave to signals of different shapes. It also comprises of maintaining the same amplitude by using an attenuator or an amplifier, and a method of switching between different forms using switches. It also utilizes a potentiometer to vary the amplitude of the signal, an amplifier coupled to the output of the potentiometer to amplify the attenuated signal, and a summing amplifier to increase or decrease the offset, with one input coupled to the signal, and the other to the offset voltage.

The digital instrumentation apparatus is provided for measuring peak amplitudes, offset, frequency, and pulse width of a PWM signal. The apparatus is comprised of a means of conditioning the inputs based on their voltage ranges, so they can be read by a microcontroller, employing attenuation for positive only signals, and the attenuation and biasing for signals that can swing between positive and negative voltages.

A square wave, which is derived from the triangle wave is connected as an input on two pins of the microcontroller to use two measurement libraries to increase the reading range of the apparatus.

An LCD is used to display the various signal characteristics on the screen according to the measurements of the microcontroller.

Software code is provided for measuring the characteristics of oscillating signals which are generated by the summing circuit. The real voltages of the peaks are calculated along with PWM control and offset in software by reversing the mathematical operations applied in hardware. The PWM control signal is further conditioned by setting a maximum, minimum value which is the peak of the stabilized triangle wave produced by the stabilizer. Then, the PWM control voltage is converted into percentage format.

The software code presents a means of checking the status of the oscillating signal chosen by the operator, which is one of three states:

1. AC state
2. Positive DC state
3. Negative DC state

The values of the maximum, minimum, and offset values depend on the state of the signal in software. The frequency of the square wave output of the apparatus is measured using two different measurement libraries, where each library has a measurement range, the two ranges overlapping. Hysteresis is used to switch between the two libraries as to avoid rapid switching between the two methods.

The Automatic gain controller (AGC) with offset stability can be implemented by employing an offset reference, which is inserted and compared with the offset in case a non-zero offset is required at the output.

The method of the manipulation of offset and amplitude of the signal may comprise the computing the maximum and minimum overall gain of the circuit, based on the supply voltage values of the amplifier, the attenuation range of the attenuator, and the voltage range of the attenuator. The gain of amplifier and summing circuits can then be chosen accordingly. This is done to make sure the output signal falls within the voltage ranges of the apparatus, and to avoid any saturation in the amplification stages.

The stabilizer further may comprise a summing circuit and a reference VT at the output of the integrator which controls the amplitude of the oscillating signal where the reference is comparable to the threshold voltage of the Mosfet employed. This way convergence may be achieved in a shorter amount of time.

The present invention also comprises the method for generating signals by relying on a signal of variable frequency and fixed shape as a reference, stabilizing the amplitude of the signal using an AGC and canceling the offset. After stabilizing the signal, signals of different shapes are derived, which are attenuated or amplified such that all signals have the same amplitudes and frequency. It also comprises of manipulating the offset and amplitude using amplifiers and summing circuits, measuring peak voltages, sampling offset from the offset control signal, and sampling pulse width from the PWM signal. These voltages are coupled to a microcontroller, which calculates the actual voltages and measures the frequency of the manipulated signal. Finally, the calculated values are displayed on the screen.

### BRIEF DESCRIPTION OF THE DRAWINGS

FIG. 1. Shows a block diagram of a model of an AGC with Offset stability model from a previous publication.

FIG. 2. Shows a block diagram of an apparatus consisting of an AGC with offset stability employing a first embodiment according to the invention.

FIG. 3. Shows a block diagram of an apparatus consisting of an AGC with offset stability employing a second embodiment according to the invention.

FIG. 4. Shows a block diagram of a system consisting of a signal manipulation scheme and digital instrumentation system.

FIG. 5. Shows the preferred embodiment of an analog function generator with digital instrumentation according to the invention.

FIG. 6. Shows a block diagram of the software code of the employed microprocessor used to measure signal characteristics of the function generator according to the invention.

FIG. 7. Shows the upper part of a block diagram of the software code of the employed microprocessor used to measure signal characteristics of the function generator according to the invention.

FIG. 8. Shows the lower part of a block diagram of the software code of the employed microprocessor used to measure signal characteristics of the function generator according to the invention.

### DETAILED DESCRIPTION AND BEST MODE OF IMPLEMENTATION

In the invention, a function generator is provided with adjustable frequency, amplitude, Pulse width, and offset, along with a digital instrumentation apparatus through a microcontroller. The function generator stabilizes an oscillating signal by analog means and eliminates the drawback of using the method of Direct Digital Synthesis. Furthermore, the output signal is fed into the microcontroller to determine signal characteristics, for both AC and DC outputs.

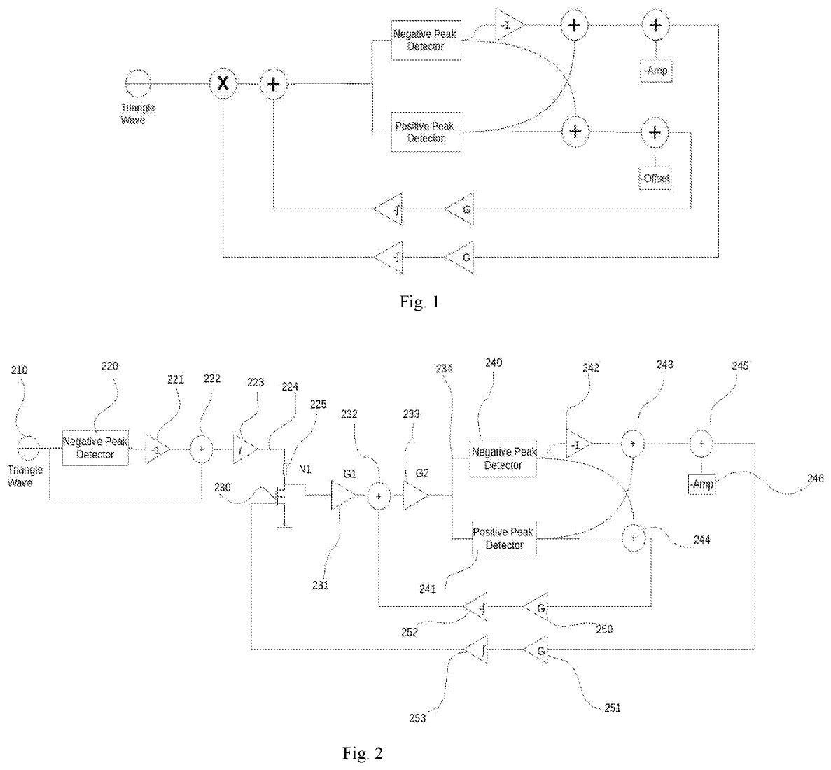

In FIG. 2, an AGC 200 for stabilizing both amplitudes and offset is provided. It consists of converting an AC triangle wave 210, which is the output of an oscillator with adjustable frequency, and a DC signal 224. Signal 224 is used as input to a multiplier and summing circuit, where the output of the multiplier is biased before it coupled to the positive and negative peak detectors. Proper circuits compute the offset and peak-to-peak amplitude. Existing amplifiers and integrators generate corresponding control signals. The control signals are fed-back to change the gain and offset level that manipulates the DC signal 224. As shown in FIG. 1, which is a simplified version of the AGC in FIG. 2, references Offset and Amp determine the output offset and amplitude of signal 234. In FIG. 1, After convergence, the output amplitude and offset equal to reference values Amp and Offset respectively. In FIG. 2 however, the reference Offset is omitted, since we desire to have zero offset in signal 234.

A DC signal 224 is generated by deriving an offset equal to the AC signal's negative peak and adding this value to the AC signal 210. The DC triangle signal 224 is used as an input to a Variable Gain Amplifier (VGA) based on attenuation, by using an attenuator made out of an NMOS transistor 230 and a resistor 225, which controls the gain of AGC. The attenuator is coupled to amplifier 231 to form the VGA. The output of the VGA is used as input to a summing amplifier 232 whose output is stable AC triangle wave 234, with zero offset and fixed amplitude.

A positive DC triangle wave 224 is derived from unstable oscillating signal 210. The negative peak of the AC signal 210 is extracted using peak detector 220, inverted by inverter 221, and finally added to signal 210 using unity gain summing circuit 222. The output of 222 is attenuated by attenuator 223 to generate positive DC triangle signal 224.

The reason for converting the triangle wave from AC to DC, and attenuating it is because it determines the voltage at the drain of transistor 230. The drain voltage should be positive, and a low drain voltage and a high enough gate voltage will help keep the transistor in the linear region, so it acts as a voltage controlled attenuator with attenuation factor N1. This attenuator output is amplified by amplifier 231 with gain G1. Amplifier 231 output is coupled to a summing amplifier represented by blocks 232 and 233 with gain G2. The multiplier and summing circuit have a combined gain of N1*G1*G2.

The Gain of the multiplier is N1*G1 while the gain of the summing circuit is G2. The reason for giving the summing circuit above unity is so the output of the multiplier doesn't get saturated before it passes to the summing circuit. Furthermore, the value N1*G1*G2 must be chosen such that it is suitable for reference voltage Amp, input voltage 224, range of N1, and the positive and negative supply voltages of the amplifiers used.

The minimum value of N1 which is N1min, along with the max value at 224, which is Vmax is the worst case scenario. We consider VSmax be the peak-to-peak supply voltage or the max peak-to-peak output amplitude. N1max is the maximum value of N1, and Vmin is the minimum value of the signal at 224.

V max*N1 min*G1*G2<VS max Eq1

V min*N1 max*G1*G2<VS max Eq2

The higher the voltage at 224 is, the lower attenuation factor N1 will be, and the opposite is true for the lowering the voltage. This way G1 and G2 can be chosen based on Equations 1 and 2, to avoid saturation at the output 234 of the AGC.

The peak amplitudes of signal 234 are sampled by positive peak detectors 241 and negative peak detector 240. Summing circuit 244 adds both peaks as they are, to compute the offset. Similarly summing circuit 243 adds the positive peak along with an inverted negative peak. This is done using unity gain inverter 242, which inverts the negative peak before both peaks are added. Summing circuit 243, therefore, computes the peak-to-peak amplitude. The output of 244 is amplified by amplifier 250, and the output of 250 is integrated by inverting integrator 252, which generates a control signal to modify the offset at 234.

Similarly, for the amplitude, a control signal is generated by amplifier 251 and non-inverting integrator 253. However, the computed peak-to-peak amplitude is compared by summing circuit 245 with a reference voltage Amp 246. This control signal controls the gain of the multiplier to set the peak-to-peak amplitude at 234. After the output is settled, the peak-to-peak amplitude at 234 is equal to the reference value Amp of comparator 245, and the offset will be zero.

The process described for sampling, computing. Generating corresponding control signals and applying them to manipulated offset and amplitude is applied recursively until the output amplitude is equal to the reference voltage, and the offset is fixed at zero with both positive and negative amplitudes equal. A reference voltage may be implemented for the offset as shown in FIG. 1, if it is desired to stabilize the offset at a specific value, but in the case of the present function generator, zero offset is required.

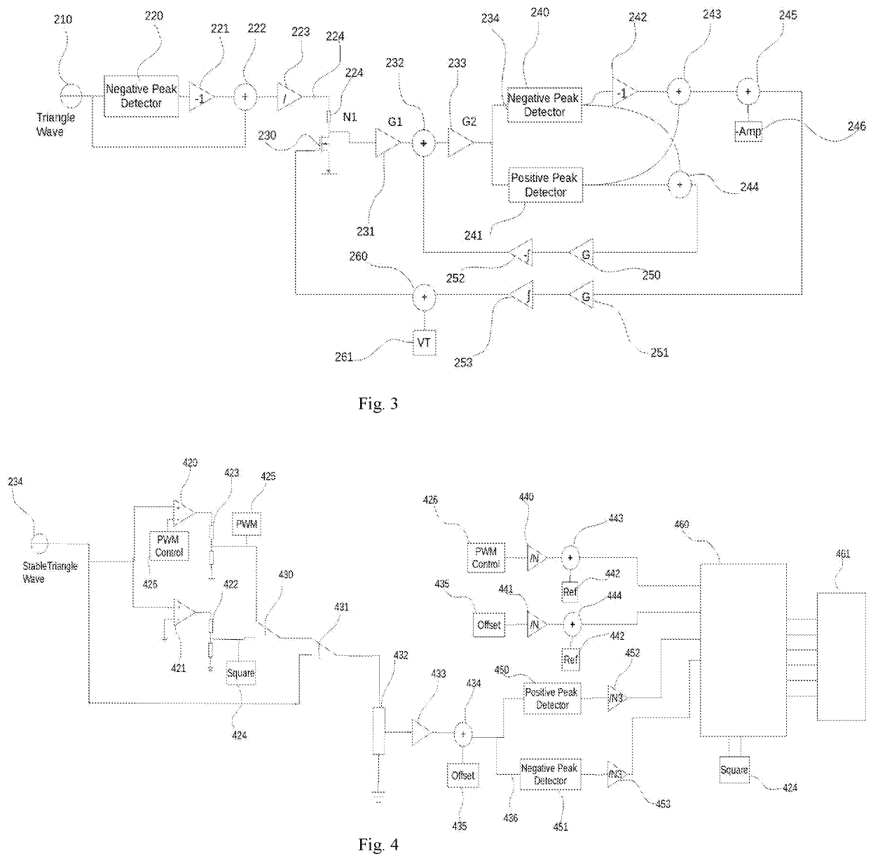

In FIG. 3, another embodiment of the AGC with offset stability is presented, which takes into account the threshold voltage of the Mosfet transistor 230. Non-Inverting integrator 253 is coupled to a summing circuit 260, which adds the gain control signal to a reference voltage VT 261, which is comparable in value to the Mosfet 230 threshold voltage. This is done because the control signal is applied to the gate, so the transistor will reach the saturation region more rapidly, and allows faster convergence. It is well known to those skilled in the art that this embodiment although useful, may not be necessary. Some may exploit the fact that a Mosfet may behave linearly in the subthreshold region, to an extent, and components 260 and 261 may be omitted. However, to ensure high performance and maintain a wide dynamic range, the addition of components 260 and 261 is more feasible.

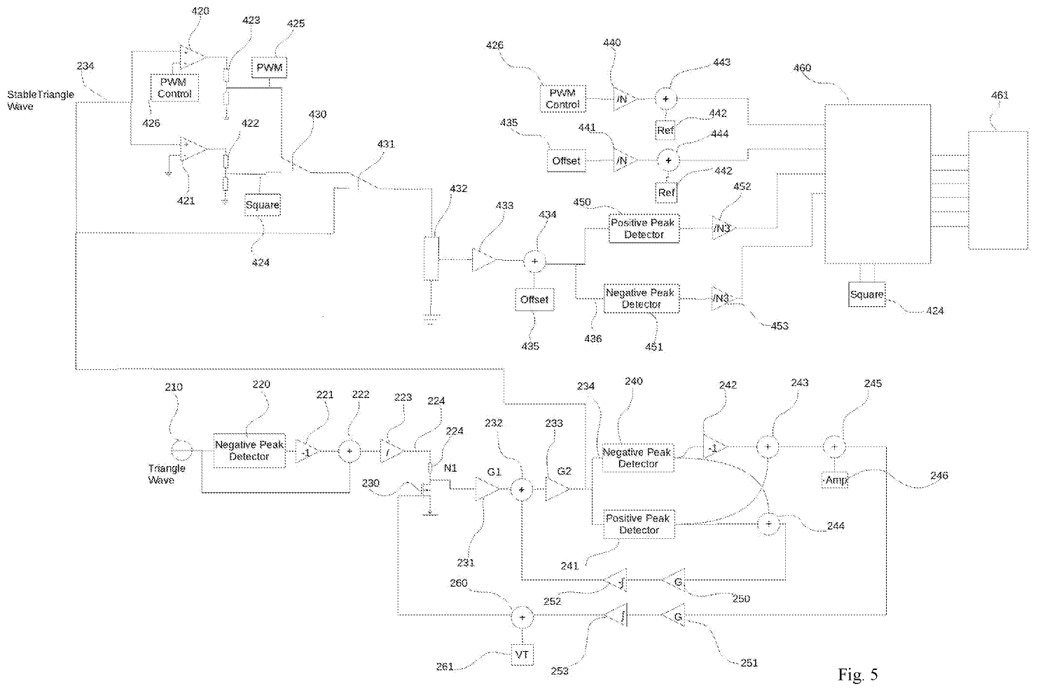

In FIG. 4, The triangle wave 234 generated by the AGC is shown in FIGS. 2 and 3 is manipulated to produce signals of different shapes while operating at the same frequency and amplitude. The operator can switch between different signal shapes using toggle switches 430 and 431. The signal chosen can be modified concerning amplitude and offset level using a potentiometer 432, and Offset voltage 435, which can be derived from the supply voltages utilizing another potentiometer. The characteristics of the chosen signal are then measured by a digital instrumentation system comprised of signal conditioning circuits, which are coupled to a microcontroller, which displays the offset, amplitudes, Pulse width, and frequency on an LCD.

Stable triangle wave 234 is coupled to comparators 420 and 421. 421 has its inverting terminal pulled to ground, and signal 234 is coupled to the non-inverting terminal. The output at 421 is a square wave with maximum peak, so to pull it down to the level of signal 234, a voltage divider 422 is employed. The output is square wave 424. Comparator 420 has its noninverting terminal coupled to signal 234, and its inverting terminal connected to reference voltage 426, which controls the pulse width of the output PWM signal 425 of comparator 420. An attenuator 423 is used to make the PWM signal amplitude equal to the amplitude of signal 234. Switches 430 and 431 are used to switch between of these three signals. It should be pointed out, that other signal shapes such as a sine wave, sawtooth wave, may also be generated and attenuated or amplified to maintain the same amplitude as that of the triangle wave, which is well known in the art, without deviating from the original spirit of the present invention.

The signal that passes by the switch configuration is coupled to a potentiometer 432, which determines the amplitude, and an amplifier 433 is used to provide a gain to be multiplied with the attenuation of potentiometer 432, resulting with an overall gain well above unity. An offset signal 435 usually derived from the supply voltage with a potentiometer is added to the output signal of amplifier 433, using summing circuit 434.

The output of summing circuit 434 is the output signal of the function generator, which needs to be monitored. The instrumentation system monitors the upper amplitude, lower amplitude, offset, and peak-to-peak amplitude, along with the frequency and width of the PWM signal. Peak detectors 450 and 451 measure the positive and negative peaks respectively. Attenuators 452 and 453 attenuate the peaks measured to enable the microcontroller to read them. PWM control signal 426 and offset signal 435 have voltage ranges higher than that of microcontroller 460 and tend to go negative which cannot be measured. So, attenuators 440 and 441 attenuate the voltages, and a reference signal 442 is added by summing circuits 443 and 444 to the attenuated signal to bring the signal to a positive voltage range measurable by the microcontroller.

The square wave 424 is used as an input to the microcontroller to measure the frequency of the signal using software techniques. The Analog to Digital Converters (ADC) of the microcontroller read the outputs of the previously described conditioning circuits of the microcontroller, and an algorithm is used to determine the state of the signal and will perform calculations to determine to signal characteristics which will be displayed on an LCD.

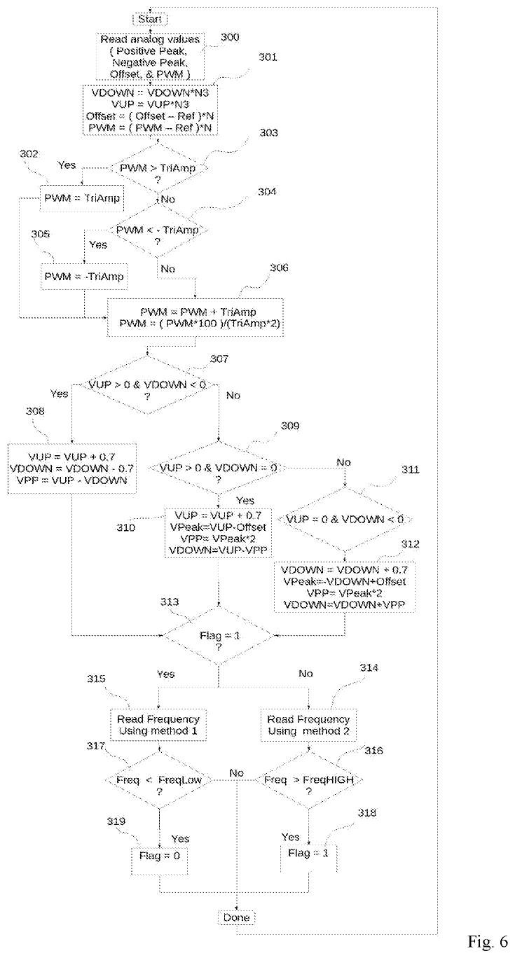

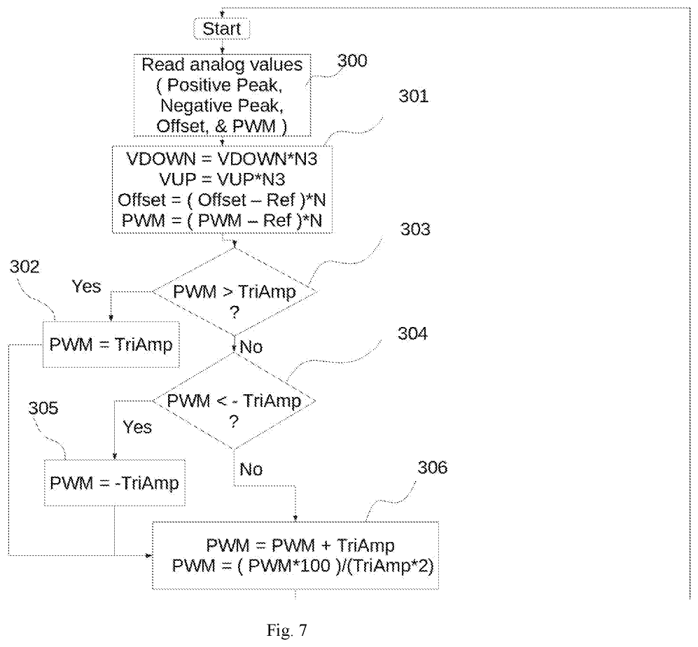

In FIG. 6, a block diagram of the software code used in microcontroller 460 is provided. The upper part of FIG. 6, is presented in FIG. 7. In block 300, the output voltage of positive peak detector 450, negative peak detector 451, PWM control signal 426, and offset 435 are read by the ADC's of microcontroller 460. In Block 301, positive and negative peaks are multiplied by constant N3, which is the attenuation factor of attenuators 452 and 453. The Offset and PWM voltages which were conditioned to be read by the microcontroller are re-calculated in software, by subtracting Reference voltage 442, and then multiplying by attenuation factor N of attenuators 440 and 441.

Since the Pulse width of the PWM signal is derived from a triangle wave, the upper peak of the triangle wave which has the same value as the absolute value of the lower peak represents 100% pulse width and the lower peak 0% pulse width. In 303, a test is made to see if the voltage of the PWM control signal 426 is greater than Triamp which is the peak for the stabilized triangle wave, which is constant across all frequencies. In 302, if the condition is true, PWM=Triamp which is 100%. In 304, a test is made to see if PWM<−Triamp. In 305, if condition is true, PWM=−Triamp which is 0%. Triamp is added to PWM, and PWM is computed in percentage format in 306.

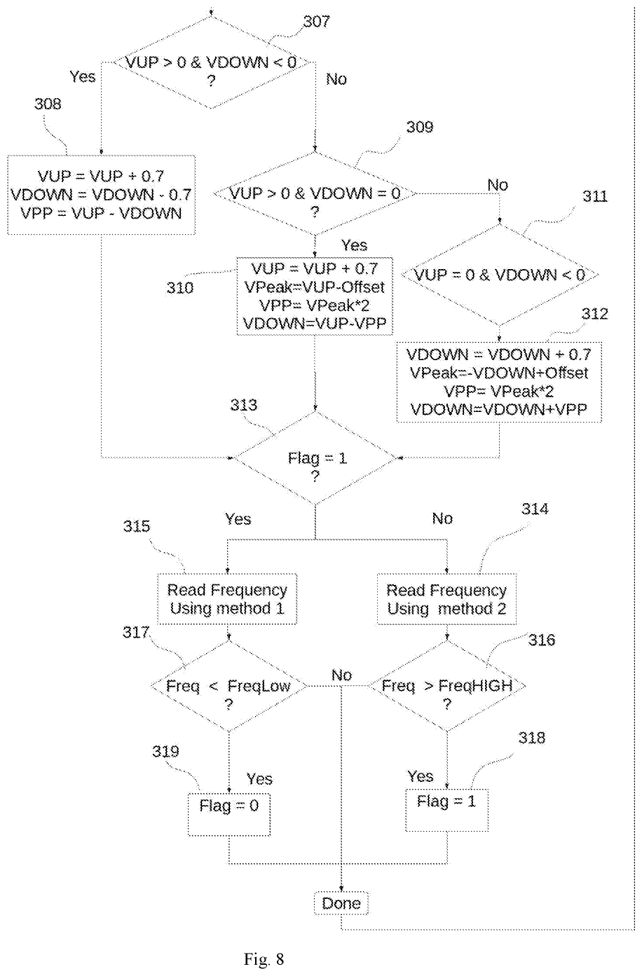

In FIG. 8, the lower part of the microcontroller code is provided. Since the output oscillating signal 436 from FIGS. 4 and 5 varies in amplitude and offset, where it can be an AC signal, as well a positive or negative DC signal, a software instrumentation method is developed for the microcontroller 460, to measure the signal's characteristics accurately.

In block 307, if positive peak detector 452 is greater than zero, and negative peak detector 453 is less than zero, 0.7 volts is added to the positive peak, and 0.7 volts is subtracted from the negative peak as shown in block 308. These 0.7 volts make up for the peak detector diodes forward voltage. To calculate offset, the upper peak is added to the negative peak. If the positive peak voltage is positive, and the negative peak is zero, this means that the oscillating signal is in positive DC State, as shown in block 309. In block 310, 0.7 Volts is added to the positive peak to get the correct upper voltage. The offset is subtracted from the actual upper voltage to determine the peak with zero offset. The peak-to-peak voltage is twice the calculated peak. The lower positive voltage is calculated by subtracting the peak-to-peak voltage from the upper voltage. In 311, if the negative peak is negative and the positive peak is zero, this means that the output signal is in negative DC State. In 312, 0.7 Volts is subtracted from the negative peak to get the exact lower voltage. The peak with zero offset is calculated by adding the offset voltage from the absolute value of the exact lower voltage. The peak-to-peak voltage is twice this peak value. To calculate the lower voltage, the negative lower peak is added to the peak-to-peak voltage.

To read the frequency of a square wave usually, there are multiple methods, probably in the form of libraries. These libraries differ in frequency ranges, where some measure a range of frequencies higher than the other. So, if these ranges overlap, as in the case of the present invention, we have exploited this circumstance. We have done this by using a well-known concept in electronics, which is hysteresis.

In block 313 a flag is tested, which can have the value zero or one. When the value is one, the first method is used which measures the higher frequency ranges, as shown in block 315. In this case, as shown in 317, if the frequency is less than a threshold voltage FreqLow, Flag is change to zero in 318 and the control loop restarts. In the other case where the frequency remains greater than FreqLow, the loop restarts directly.

In block 313, if the flag is equal to zero, the frequency is read using method 2 as shown in block 314. This method measures the lower frequency range. In 316, if the frequency is higher than a threshold voltage FreqHigh, Flag is set to one in block 318. If the frequency remains less than FreqHigh, the control loop restarts directly.

Thus, the code for the microcontroller keeps re-measuring the signal characteristics in realtime and displays the values on LCD 461, using methods that are well known in circuit design.

The invention provides a means of stabilizing an unstable triangle wave, which tends to deviate over a wide frequency range, and uses the stabilized signal as a reference to derive other signals of different shapes, however with the same frequency, amplitude, frequency, and offset. The operator chooses the signal shape and will manually set the amplitude and offset level. The amplitude, offset, frequency, and pulse width of the output signal are measured using conditioning circuits which interface to a microcontroller. The software code of the microcontroller converts the analog reading to an understandable form and displays the output on an LCD.

The invention will appear to those skilled in the art of the practice and specification of the system disclosed. The examples should be considered as exemplary, with the scope of this invention indicated by the following claims.

1. A function generator based on triangle wave input from an oscillator with an adjustable oscillation frequency, the function generator comprising:
An first apparatus for stabilizing a triangle wave by means positive and negative peak detection, by computing peak-to-peak amplitude and offset, and comparing these computed values to reference voltages, where the output of the comparators being amplified and integrated, and then fed-back to the input until offset and amplitude are stable and equal to fixed reference values.
A second apparatus which converts the stable triangle wave output of the first apparatus into signals of different function but with the same amplitude, and offset. The signals being amplified or attenuated after conversion to make sure signal characteristics are identical. The signal shapes being switched from one to the other using toggle switches.
A method to manipulate the chosen function by coupling the signal to a potentiometer, an amplifier, and a summing circuit to change the offset and peak-to-peak amplitude.
A method of choosing the gain of the amplifier and summing circuit based on the overall gain, voltage ranges and saturation voltages of the apparatus.
A third apparatus for measuring maximum and minimum peak of the signal manipulated by the operator regardless whether the signal is DC or AC. The apparatus reads the conditioned PWM control, offset, along with the outputs of the peak detectors using a microcontroller. The apparatus also reads the frequency of the square wave output on two pins.
A software method for calculating the actual values of signal characteristics after extracting these from the hardware conditioned inputs of the microcontroller.

2. An Automatic gain control apparatus for stabilizing the peak-to-peak amplitude and offset of any oscillating signal simultaneously, the apparatus comprising:
A variable gain amplifier for stabilizing the amplitude of the output oscillating signal.
A summing circuit to change the offset level of the output oscillating signal.
Two peak detectors, where the first determines the positive peak of the signal and the second determines the negative peak.
A means of computing the peak-to-peak amplitude and the offset the signal.
A means of comparing the computed amplitude and offset to a fixed reference voltage.
An amplifier for amplifying the difference between the amplitude values and Amp reference voltage
An amplifier for amplifying the offset which us the some of the positive and negative peaks.
A means of integrating the amplified differences using integrators for both amplified signals
The output of the integrators being fed-back to the Variable gain amplifier and the summing circuit to complete the loop

3. A variable gain amplifier comprising:
A conditioning circuit for bringing the AC signals to positive DC.
A Mosfet transistor is acting a voltage controlled attenuator.
The drain of the Mosfet being coupled to an amplifier to increase the gain to well above unity.

4. An apparatus for generating signals of different shapes and magnitudes, which relies on a variable frequency stable triangle wave as a reference. The apparatus comprising:
A means of converting the triangle wave into signals of different shapes, while maintaining the same amplitude, and frequency by using an attenuator or an amplifier.
A means of switching between different shapes using switches.
A potentiometer to vary the amplitude of the signal
An amplifier coupled to the output of the potentiometer to amplify the attenuated signal
A summing amplifier to increase or decrease the offset, with one input coupled to the signal, and the other to the offset voltage.

5. A digital instrumentation apparatus for measuring peak amplitudes, offset, frequency, and pulse width of a PWM signal. The apparatus comprising:
A means of conditioning the inputs based on their voltage range so that a microcontroller can read them.
A means of attenuation for positive only signals.
A means of attenuation and biasing for signals that can swing between positive and negative voltages.
Connecting the square wave input which is derived from the triangle wave to two pins of the microcontroller to use two measurement libraries to increase the reading range of the system.
An LCD to visually show the various signal characteristics on the screen according to the measurements of the microcontroller.

6. A method for measuring the characteristics of oscillating signals generated by the apparatus in claim 4. The method comprising:
Extracting the real voltages of the peaks, PWM control, and offset in software by reversing the mathematical operations applied in hardware.
Further extracting the PWM control signal by setting a maximum, minimum value which is the peak of the stabilized triangle wave produced by the apparatus in claim 2. Then, the PWM control voltage is converted into percentage format
A means of checking the status of the oscillating signal chosen by the operator, which is one of three states:
AC state
Positive DC state
Negative DC state
Extracting the values of the maximum, minimum, and offset values depending on the state of the signal in software.
Measuring the frequency of the square wave output of the apparatus in claim 4 while relying on two different measurement libraries, each library has a measurement range, the two ranges overlapping.
Using hysteresis to switch between the two libraries as to avoid rapid switching between the two methods.

7. The apparatus according to claim 2 further comprising an offset reference being inserted and compared with the output offset in case a non-zero offset is required.

8. The method according to claim 7 further comprising the computing the maximum and minimum overall gain of the circuit, based on the supply voltage values of the amplifier, the attenuation range of the attenuator, and the voltage range of the attenuator. The gain of amplifier and summing circuits can then be chosen accordingly.

9. The apparatus according to claim 8 further comprising a summing circuit, and a reference VT at the output of the integrator which controls the amplitude of the oscillating signal, where the reference is comparable to the threshold voltage of the Mosfet employed.

10. The apparatus according to claim 9 further comprising the Variable Gain Amplifier provided in claim 3.

11. The function generator according to claim 1 further comprising the apparatus provided in claim 10.

12. The digital instrumentation apparatus according to claim 5 further comprising the method provided in claim 6.

13. The function generator according to claim 11 further comprising the digital instrumentation apparatus in claim 12.

14. A method for generating signals comprised of:
Relying on a signal of variable frequency and fixed shape as a reference.
Stabilizing the amplitude of the signal using an AGC.
Canceling offset.
The deriving signal of different shapes.
Attenuating or amplifying derived signals such that all have the same amplitude.
Manipulating offset and amplitude using amplifiers and summing circuits.
Measuring peak voltages.
Sampling offset from the offset control signal.
Sampling pulse width from the PWM signal.
Coupling sampled voltages to a microcontroller.
Sampling signal frequency using a microcontroller.
Display signal characteristics on screen.
